(19) United States
(12) Patent Application Publication
(10) Pub. No.: US 2010/0219526 A1
(43) Pub. Date: Sep. 2, 2010

(54) FLEXIBLE MICROELECTRONICS ADHESIVE

(76) Inventors: RUSSELL STAPLETON, Apex, NC (US); Robert Kyles, Middlesex, NC (US); David Zoba, Apex, NC (US); Kathleen Gilbert, Pittsboro, NC (US); Sara N. Paisner, Chapel Hill, NC (US)

Correspondence Address: LORD CORPORATION;PATENT & LEGAL SERVICES, 111 LORD DRIVE, P.O. Box 8012, CARY, NC, 27512-8012, US

(21) Appl. No.: 12/775,839

(22) Filed: May 7, 2010

Related U.S. Application Data
(63) Continuation of application No. 11/850,726, filed on Sep. 6, 2007, now abandoned.
(60) Provisional application No. 60/824,983, filed on Sep. 8, 2006.

(51) Int. Cl. H01L 23/34

(52) U.S. Cl. 257/712; 257/E23.08

(57) ABSTRACT

A curable thermal interface material is provided comprising a functionalized elastomer and a filler. Preferred materials comprise an epoxidized polybutadiene cured with an iodonium catalyst and a filler comprising silver and/or aluminum oxide.

### CROSS REFERENCE TO RELATED APPLICATIONS

The present application is a continuation of U.S. patent application Ser. No. 11/850,726, filed Sep. 6, 2007, which claims priority under 35 U.S.C. §119(e) from U.S. Provisional Patent Application Ser. No. 60/824,983, filed Sep. 8, 2006, entitled “FLEXIBLE MICROELECTRONICS ADHESIVE”, the disclosure of each of which is incorporated herein by reference.

### FIELD OF THE INVENTION

The invention relates to a conductive adhesive material comprising a resin and conductive filler particles. The adhesive is particularly well suited for use in thermal interface die assemblies and is placed between the die and the lid, lid and heat sink and/or die and heat sink to facilitate flow of heat away from the die. The adhesive comprises a low modulus adhesive resin component and a thermally conductive filler.

### BACKGROUND OF THE INVENTION

Surface mounting of electronic components is well developed in automated package assembly systems. Interface adhesives are used in several approaches to provide lid attach, sink attach and thermal transfer from flip chip devices, as well as against mechanical shock and vibration encountered in shipping and use. As semiconductor devices operate at higher speeds and at tighter line widths, the thermal transfer properties of the adhesive are critical to device operation. The thermal interface adhesive must create an efficient thermal pathway between the die or lid and the heat sink as the adhesive itself due to interface resistance (Θint) and bulk resistance (Θadh) is typically the most thermally resistant material in the die-adhesive-lid-adhesive-sink or die-adhesive-sink configuration.

The thermal interface adhesive must also maintain efficient thermal transfer properties through reliability testing which simulates actual use conditions over the life of the device. The adhesive must not delaminate from the substrates or the bulk thermal resistance of the adhesive will degrade after exposure to the reliability testing, thereby causing failure of the package. The interface adhesive may be applied after the reflow of the metallic or polymeric interconnect and after curing the underfill. A measured amount of interface adhesive will be dispensed usually on the die surface and on the periphery of the carrier substrate in a lidded flip chip assembly (Θjc). The adhesive may also be dispensed on the top of the die surface and the heat sink placed in a die-to-sink application (Θja). Additionally, the adhesive can be dispensed on the lid surface and the heat sink placed in a sink-to-lid application (Θca). After the adhesive is dispensed, the adherends are placed with a predetermined pressure and time. The assembly is then heated to cure the adhesive.

Current thermal interface adhesives typically comprise inorganic-filled polymeric resins. The resins are poor thermal conductors, but provide a medium to transport the fillers to the die/lid interface. The resin also provides a structural element, providing adhesion between the lid and the die. The inorganic fillers must be more thermally conductive than the resin. The inorganics can be mixtures of metals, ceramics, and glasses. Most commonly the filler comprises aluminum, silver, zinc oxide, or boron nitride. The resins typically comprise epoxy, silicone, acrylates, amines or mixtures thereof.

A suitable adhesive must have certain shelf life, fluid handling/dispensing characteristics, and exhibit specific adhesion, appropriate cure time and temperature, controlled shrinkage, specific thermal coefficient of expansion, and low corrosivity in order to provide long term defect-free service over the thermal operating range of the electronic circuit package. Desired properties for thermal interface materials are known such as sharp, well-defined, stable and reproducible Tg, an initial high and stable thermal conductivity, and ability to withstand high temperature and voltage during repeated “switching” cycles without loss of any of these properties. However, adhesives fulfilling all of the requirements are not easily found.

A drawback to highly filled thermosetting epoxy resin compositions currently used in microelectronics applications, such as for underfills or thermal interface materials, is their extended cure schedule and useful working life at dispensing temperatures and ability to remain at a stable viscosity until curing is initiated. Also, the high modulus exhibited by epoxy resins reduces their ability to withstand package stress particularly during thermal cycling. This problem can be eliminated by employing a low modulus material, such as silicones, however silicones are known for poor adhesion and their ability to resist flow and remain in place on the substrate often requires additional attachment and containment means.

Another approach has been to combine resins so as to extract certain desirable properties of each into a final formulation. Commonly, an amine or an epoxy is mixed with an elastomeric resin in an attempt to provide good adhesion along with low modulus. It would be desirable to provide these properties by employing a single elastomeric resin.

Provided that a stable adhesive can remain at an appropriate viscosity during continuous dispensing, a balance of properties in the cured solid-phase thermal interface adhesive are needed and are affected by the matrix composition. Besides maintaining filler level above 70 volume percent in a n adhesive with syringe dispensable viscosity, the organic components also contribute significantly to the resulting cured thermal conductivity, shrinkage, coefficient of thermal expansion (CTE) and therefore essential for long term, defect-free service in the assembled devices after thousands of temperature cycled from as low as −55° C. to as high as 125° C.

It is therefore desirable to provide a curable thermal interface material with the above-described properties which exhibits good adhesion to the substrate while maintaining low modulus so as to withstand package stresses.

### SUMMARY OF THE INVENTION

In a first aspect of the present invention, a curable thermal interface material is provided which is flexible, thermally conductive, and exhibits desirable properties heretofore unseen in microelectronics adhesives. The flexibility of the adhesive allows the package to survive mechanical stresses from heating and cooling cycles that cause high modulus materials to fail. As such an embodiment of the present invention is particularly useful for microelectronic adhesive applications where thermal conduction is required such as, die attach, lid attach, and heat sink attach. The combination of low modulus and high adhesion allows this material to be used in high or low stress applications. Additionally, the formulations of the embodiments of the present invention do not require the use of supplemental adhesive or mechanical attach methods to keep package together.

In one embodiment of the present invention, the thermal interface material comprises a resin and a thermally conductive filler. The resins for use in the present invention comprise elastomers, such as rubber with a Tg below room temperature. For the purposes of this invention “room temperature” means about 10° C. to about 40° C., typically about 20° C. to about 25° C., but is understood to also encompass the working conditions and/or application conditions in the environment where thermal interface adhesives are made and used.

In a further embodiment of the present invention, an epoxidized butadiene rubber is cured with a cationic initiator, preferably an iodonium salt. This combination of resin and initiator has proved successful with a variety of fillers and exhibits exceptional adhesion to dies and lids. Additionally, other additives such as diluents, thixotropes, adhesion promoters, and the like may be included depending upon the particular application.

In a preferred embodiment of the present invention, the epoxidized butadiene rubber comprises an epoxidized hydroxyl terminated polybutadiene having a molecular weight of about 1350, an epoxy value of 2.2(meq/g), and an epoxy equivalent weight of about 460. In another preferred embodiment of the present invention, the iodonium initiator comprises (p-isopropylphenyl)(m-methylphenyl)iodonium tetrakis(pentafluorophenyl)borate.

The critical fluid properties for high speed dispensing of thermal interface embodiments are: viscosity less than about 10,000 poise measured using a Haake® RS1 cone and plate controlled stress rheometer at 25° C. at 2.0 l/sec using a 1 degree, 35 mm cone. The preferred viscosity in accordance with the invention was observed in a range of from 1200 poise to 6000 poise at 2.0 l/sec. The thixotropic index as the ratio of viscosity at 0.2 l/sec to viscosity at 2.0 l/sec is in a range of from 3 to about 7. In a 24-hour period at 25° C. the invention exhibits a viscosity stability of less than 30 percent viscosity variation over 24 hours. The invention provides sufficient flow and wetting of the dispensed adhesive material to the parts to be bonded when dispensed from a syringe or printed utilizing a screen printer, as practiced on conventional automated assembly lines.

The materials of the embodiments of the present invention are particularly suitable for microelectronics applications. The materials of the various embodiments of the present invention exhibit high bulk thermal conductivity coupled with good modulus and adhesion. This combination of properties has not been seen in prior thermal interface materials having a single elastomeric resin matrix. The materials of the embodiments of the present invention also exhibit other desirable characteristics such as dispensability, low bond line thickness, interfacial resistance, delamination resistance, and minimal shrinkage.

### DETAILED DESCRIPTION OF THE PREFERRED EMBODIMENTS

In a first embodiment of the present invention, a curable thermal interface material is provided comprising a functionalized elastomer and a filler. The elastomers employed in the present invention include those which have a Tg of less than room temperature and provide a modulus of less than 1 gigapascal at room temperature and an adhesion to the substrate measured by a die shear of at least 500 psi in the final cured material.

In another embodiment of the present invention, suitable elastomers include natural rubber, polyisoprene, epoxidized natural rubber, nitrile, polybutadiene, polyisobutylene, butyl rubber, polystyrene-co-butadiene, polystyrene-co-isoprene, polychloroprene, also known as neoprene, bromobutyl rubber, clorobutyl rubber, chlorosulfonated polyethylene rubber, polyethylene-co-olefin rubbers, olefin based rubbers for example: chlorinated polyethylene elastomer; terpolymer elastomers made from ethylene-proplylene-diene monomer, fluoroelastomers and mixtures thereof.

In another embodiment of the present invention, the preferred elastomer comprises epoxidized rubber. Their degree of epoxidation may vary widely, according to the extent of the epoxidation reaction to which the natural rubber is subjected. According to the invention epoxidized rubbers having degrees of epoxidation ranging from 25 to 75 molar percent are particularly advantageous. In a preferred embodiment of the invention, epoxidized rubbers are used having an epoxy value of approximately 2.2 meq/g.

In a preferred embodiment of the present invention, the preferred elastomer comprises a functionalized diene rubber. The term “diene rubber” is intended to be a broad usage of the term to include any rubber whose structure is based on a conjugated diene, whether a natural rubber, or a synthetic rubber prepared by such as the well known emulsion or solution processes.

These diene rubbers can be composed of or prepared from one or more conjugated dienes, alone, or in combination with a copolymerizable monomer such as a monovinylarene or other comonomer, so long as the resulting polymer exhibits rubbery or elastomeric characteristics.

The synthetic diene rubbers can be simple homopolymers such as polybutadiene or polyisoprene; or can be linear containing two or more blocks of polymer derived from the same or different monomers; can be coupled or uncoupled, or radial; and the polymer structure can be random or block or mixed. Rubbery graft copolymers also are appropriate as are other rubbery types suitable generally for rubber traction surfaces including application of tires. Multiblock structure can arise by various types of coupling such as dichain coupling, coupling with multifunctional treating agents, various modes of preparation such as sequential monomer addition, or other techniques well known in the art.

Presently preferred are rubbery diene polymers exhibiting, before curing, molecular weights in the range of about 50,000 to 500,000, preferably about 75,000 to 300,000 for ease of handling, including during the epoxidation stage and subsequent processing and fabrication.

Aside from the natural rubber which we include as a “diene rubber”, the diene rubbers can be prepared from polymerizable conjugated dienes, generally those in the range of 4 to 12 carbon atoms per molecule for convenience and availability, with those containing 4 to 8 carbon atoms being preferred for commercial purposes, most preferred for the diene rubbers are butadiene and isoprene because of their known highly desirable characteristics and availability. Examples include 1,3-butadiene and isoprene, as well as 2,3-dimethyl-1,3-butadiene, piperylene, 3-butyl-1,3-octadiene, 2-phenyl-1,3-butadiene, and the like, alone or in admixture. As suitable conjugated diene feedstock for polymerization products, particularly in the solution polymerization processes, 1,3-butadiene can be employed in admixture with other low molecular weight hydrocarbons, such admixtures being termed low concentration diene streams, obtainable from a variety of refinery product streams such as from naphtha cracking operations and the like and may contain such as 30 to 50 weight percent 1,3-butadiene though this can range widely.

Particularly presently preferred rubbers are the polybutadienes, polyisoprenes, and butadiene or isoprene styrene copolymers.

The rubbery diene polymer, prior to compounding and curing, in accordance with our invention is epoxidized. Epoxidation can be effected by the use of epoxidizing agents such as a peracid such as m-chloroperbenzoic acid, peracetic acid, or with hydrogen peroxide in the presence of a carboxylic acid such as acetic acid or formic acid with or without a catalyst such as sulfuric acid. Carboxylic anhydrides can be employed as alternatives to the corresponding carboxylic acids. For example, acetic anhydride can be used in place of acetic acid. The use of the anhydride has the effective result of providing a higher concentration of peracid formed in situ than would be the case if the corresponding carboxylic acid had been employed. Other acids and acidic agents can be employed in place of the aforementioned sulfuric acid, e.g., p-toluenesulfonic acid or a cationic exchange resin such as a sulfonated polystyrene.

Epoxidation is conducted employing a solvent capable of substantially dissolving the diene rubbers in their original condition as well as after being epoxidized. Suitable solvents are generally aromatic solvents such as benzene, toluene, xylenes, chlorobenzene, as well as cycloaliphatic such as cyclohexane, and the like.

Epoxidation should be conducted at a temperature in the range of about 0° C. to 150° C., presently preferred about 25° C. to 80° C., because of useful reaction rate with a minimum of side-reactions, employing a time sufficient to achieve the degree of epoxidation desired which is that degree sufficient to markedly improve the adhesion and modulus of the ultimately cured composition. Exemplary times are in the range of about 0.25 to 10 hours, presently preferred as being generally satisfactory and convenient at about 0.5 to 3 hours. Higher reaction temperatures generally mean shorter reaction times being needed, and where it is more convenient to employ lower temperatures, then usually a somewhat longer epoxidation time should be practiced.

The concentration of active epoxidizing agents presently exemplarily can be in the range of about 1 to 100 weight percent relative to the weight of polymer to be epoxidized, presently preferred about 4 to 30 weight percent relative to the weight of polymer.

Presently recommended is an extent of epoxidation, defined as the percentage of originally present olefinically unsaturated sites in the diene rubber which has been converted to oxirane, hydroxyl, and ester groups, about 5 to 95 percent, presently preferred about 10 to 50 percent.

In a most preferred embodiment of the present invention, the functionalized elastomer is present to the exclusion of non-preferred but common thermal interface materials. As discussed previously, epoxies and silicones have a balance of properties which are inconsistent with the functional requirements of thermal interface materials. For this reason these materials should be excluded from the thermal interface material of an embodiment of the present invention. In an additional embodiment of the present invention, thermoplastic elastomers, such as co-polyesters, polyurethanes, and polyamids are substantially absent from the thermal interface material. Additionally, commonly added polymers such as polyacrylates are not suitable for use in the present invention and the thermal interface materials of the present invention, are substantially absent such compounds. Manu of these compounds are hydrophilic in nature and will absorb atmospheric moisture which degrades the strength and adhesiveness during thermal cycling.

The curable thermal interface material of the present invention may be cured according to methods known in the art. In a preferred embodiment of the present invention a cationic initiator is employed to cure the material. Examples of suitable cationic initiators include onium moieties, such as ammonium, phosphonium, arsonium, oxonium, sulfonium, selenonium, telluronium, iodonium. In a most preferred embodiment of the present invention, a cationic initiator based in iodonium is employed.

The initiator is preferably employed in the curable composition in an amount from about 0.01 to about 0.50, preferably about 0.10 to about 0.30, and most preferably from about 0.12 to about 0.22 weight percent based on the total weight of the material.

In another embodiment of the present invention, a conductive filler is employed, the selection of which is dependent upon on the particular end-use intended as disclosed herein. Available thermally conductive particulate fillers include silver, alumina, aluminum nitride, silicon nitride, boron nitride, silicon carbide, and combinations thereof. Preferred are combinations of silver flakes and/or powdered silver optionally in combination with a filler selected form the group consisting of graphite, metal oxide, metal carbide, metal nitride, carbon black, nickel fiber, nickel flake, nickel beads and copper flake.

In adhesive embodiments such as encapsulants, other than silver-filled thermal interfaces, inorganic oxide powders such as fused silica powder, alumina and titanium oxides, and nitrates of aluminum, titanium, silicon, and tungsten are present excluding silver. The use of these fillers will result in different rheology as compared with the low viscosity silver-filled thermal interface adhesive embodiments but the organic component provides moisture absorption resistance. These fillers may be provided commercially as pretreated with a silane adhesion/wetting promoter.

In one embodiment of the present invention, the material is highly-filled to provide good thermal and/or electrical conductivity. In a further embodiment of the present invention, the filler comprises about 75 to about 90 percent by weight of the total composition. In a still further embodiment of the present invention, the filler comprises from about 82 to about 89 percent and in a still further embodiment of the present invention from about 84 to 88 percent by weight based on the total weight of the composition.

Other additives which are not essential will be typically included in commercial practice, as some of the examples below illustrate. Additives such as carbon black or a tinting agent or coloring agent, adhesion promoters, wetting agents and the like can be included. One or more types of functionalized organosilane adhesion promoters are preferably employed directly and/or included as an aforementioned pretreatment to fillers as a tie-coat between the particulate fillers and the curable components coating of the invention. The silane additives employed typically at 1 to 3 weight percent of the organic component directly to provide adhesion promoting and wetting improvement between the fluid adhesive and the substrates to be bonded. Representative organofunctional silane compounds useful in the present invention can include (A) hydrolysis reaction products of a tetraalkoxysilane, an organopolysiloxane containing at least one alkenyl radical or silicon-bonded hydrogen atom and an acryloxy-substituted alkoxysilane as is taught in U.S. Pat. No. 4,786,701; (B) alloy silane adducted with acrylate or methacrylate; (C) a combination of epoxy- and vinylfunctional organosilicon compounds as described in U.S. Pat. No. 4,087,585; (D) an epoxyfunctional silane and a partial allyl ether of a polyhydric alcohol.

### Exemplary Uses

Lid-Die Interface

The thermally conductive adhesive which forms the heat bridge between the die and the metal lid can be pre-applied to the lid on the undersurface which will face the die. Lids currently in existence vary widely in length, width and depth, but are generally rectangular in shape, with a peripheral rim or flange which provides a surface along which the lid can be bonded to the substrate. The central portion of the lid is recessed relative to the flange to provide the concave shape, and is generally planar.

Die Attach Adhesives

Die attach adhesives are used to attach semiconductor chips, i.e., to lead frames. Such adhesives must be able to be dispensed in small amounts at high speed and with sufficient volume control to enable the adhesive to be deposited on a substrate in a continuous process for the production of bonded semiconductor assemblies. Rapid curing of the adhesives is very desirable. It is also important that the cured adhesives demonstrate high adhesion, high thermal conductivity, high moisture resistance and temperature stability and good reliability. Conductive die attach adhesives prepared in accordance with the present invention comprise the resin composition of the present invention and at least one conductive filler. Electrically conductive adhesives typically include at least one type of silver flake. Other suitable electrically conductive fillers include silver powder, gold powder, carbon black and the like. For a thermally conductive adhesives (without electrical conductivity) fillers such as silica, boron nitride, diamond, carbon fibers and the like may be used. The amount of electrically and/or thermally conductive filler is sufficient to impart conductivity to the cured adhesive, preferably an amount of from about 20 percent to about 90 percent by weight and more preferably from about 40 percent to about 80 percent by weight. In addition to the electrically and/or thermally conductive filler, other ingredients such as adhesion promoters, anti-bleed agents, rheology modifiers, flexibilizers and the like may be present.

Glob Top Encapsulants

Encapsulants are resin compositions which are used to completely enclose or encapsulate a wire bonded die. An encapsulant prepared in accordance with the present invention comprises the organic component composition of the present invention and non-conductive fillers such as silica, boron nitride, carbon filer and the like. Such encapsulants preferably provide excellent temperature stability, e.g., able to withstand thermocycling from −55° C. to 125° C. for 1000 cycles; excellent temperature storage, e.g., 1000 hours at 150° C.; are able to pass a pressure cooker test at 121° C. at 14.7 p.s.i. for 200 to 500 hours with no failures, and are able to pass a HAST test at 140° C., 85 percent humidity at 44.5 p.s.i. for 25 hours with no failures.

Heat Sink Adhesive

As mentioned above, the heat cured interface embodiment of the present invention is readily adapted to provide a thermal interface directly between a heat sink or integrated heat spreader, in a semiconductor package and the semiconductor die (Level 1), and between the lid and the heat sink (Level 2).

### Example 1

| Material | Weight Percent |
|---|---|
| Epoxidized Polybutadiene | 9.4 |
| diglycidyl ether of neopentyl glycol | 2.3 |
| Alkyl C12-C14 glycidyl ethers | 0.50 |
| Silver | 87.4 |
| Iodonium salt | 0.15 |
| Other Additives | 0.25 |

### Formula Properties Summary:

| | | |
|---|---|---|
| Bulk Thermal Conductivity | 10.3 | W/mK |
| Die shear adhesion (silicon die on Ni plated Cu | 2000 | psi |
| substrate): | | |
| Modulus (by DMTA at 25° C.) | 760 | Mpa |
| Viscosity (at 25 C. at 1 1/s) | 310,000 | cP |

### Example 2

| Material | Weight Percent |
|---|---|
| Epoxidized Polybutadiene | 10.4 |
| Aluminum | 68.04 |
| Zinc Oxide | 15.45 |
| diglycidyl ether of neopentyl glycol | 3.96 |
| Resin Preblend¹ | 2.15 |

¹Preblend is a 2 percent by weight polybutadiene and 0.15 percent by weight Iodonium salt.

### Example 3

### Non Electrically Conductive Thermally Conductive Die Lid Attach Adhesive

| | Formulation | Formulation | Formulation |
|---|---|---|---|
| Material | A (wt %) | B (wt %) | C (wt %) |
| Epoxidized Polybutadiene | 11.87 | 11.90 | 11.95 |
| Iodonium Initiator | 0.12 | 0.12 | 0.12 |
| diglycidyl ether of | | | |
| cyclohexane dimethanol | 1.47 | 1.18 | 0.79 |
| diglycidyl ether of 1,4- | | | |
| butanediol | 0.20 | 0.20 | 0.20 |
| Silane Adhesion Promoter | 2.11 | 2.12 | 2.13 |
| Zinc Oxide (0.12 micron) | 41.48 | 41.61 | 41.77 |
| Silver | 42.76 | 42.88 | 43.05 |

Iodonium initiator = (p-isopropylphenyl)(m-methyphenyl)iodonium tetrakis(pentafluorophenyl)borate

### Formulation Properties:

| | | Visc.(Pa · s) | | BTC | Die |
|---|---|---|---|---|---|
| Formulation | 1 1/s | 5 1/s | 10 1/s | W/mK | Shear psi |
| A | 552.7 | 215.2 | 168.1 | 2.365 | 2161 |
| B | 527.4 | 195.9 | 148.2 | 2.305 | 2191 |
| C | 655.8 | 251.5 | 194.7 | 2.439 | 2105 |

### Example 4

### Non Electrically Conductive Thermally Conductive Lid Attach Adhesive

| Material | (weight percent) |
|---|---|
| Epoxidized Polybutadiene | 21.73 |
| Iodonium Initiator | 0.22 |
| Silane Adhesion Promoter | 3.57 |
| Zinc Oxide (0.21 microns) | 66.20 |
| Boron Nitride Powder (45 microns) | 8.28 |

| | | Visc.(Pa · s) | | | BTC |
|---|---|---|---|---|---|
| Formulation | Lot # | 1 1/s | 5 1/s | 10 1/s | W/mK |
| SNP9510-42 | 9540-43 | 574.6 | 530.9 | 596.1 | 1.191 |

What is claimed is:

1. A microelectronics package comprising:
a die; and,
a thermal interface material disposed on at least one side of the die, wherein the thermal interface material comprises an epoxy functionalized elastomer and a thermally conductive filler and wherein the resin is substantially free of aromatic and cycloaliphatic epoxies, amines, silicones, and esters.

2. The package of claim 1, wherein the thermal interface material is substantially free of thermoplastic elastomers.

3. The package of claim 1, wherein the functionalized elastomer comprises a functionalized diene rubber.

4. The package of claim 3, wherein the functionalized diene rubber comprises an epoxy functionalized polybutadiene.

5. The package of claim 1, further comprising an adhesion promoter.

6. The package of claim 5, wherein the adhesion promoter comprises a vinyl silane.

7. The package of claim 1, further comprising an iodonium initiator.

8. The package of claim 7, wherein the iodonium initiator comprises (p-isopropylphenyl)(m-methylphenyl)iodonium tetrakis(pentafluorophenyl)borate.

9. The package of claim 1, wherein the thermally conductive filler comprises at least one of silver, alumina, zinc oxide, aluminum nitride, silicon nitride, boron nitride, and silicon carbide.

10. The package of claim 9, wherein the thermally conductive filler comprises silver.

11. The package of claim 1, wherein the filler is present in an amount from about 82 to about 88 weight percent by weight based on the total weight of the thermal interface material.

12. The package of claim 1, wherein the thermal interface material is elastomeric at room temperature.

13. The package of claim 1, wherein the adhesive strength as measured by die shear adhesion of a silicon die on Ni plated Cu substrate of at least 2000 psi.

14. The package of claim 1, wherein the modulus of the thermal interface material after curing comprises less than about 1.0 gigapascal.

15. The package of claim 1, wherein the thermal interface material is syringe dispensable.

16. The package of claim 1, wherein the thermal interface material consists essentially of an epoxy functionalized elastomer, a conductive filler, and iodonium initiator, and an adhesion promoter.

17. The package of claim 16, wherein the conductive filler comprises a thermally conductive filler.
